(19) United States
(12) Patent Application Publication
(10) Pub. No.: US 2025/0266799 A1
(43) Pub. Date: Aug. 21, 2025

(54) BIASING CIRCUIT

(71) Applicant: ADVANTEST CORPORATION, Tokyo (JP)

(72) Inventor: Fumikazu TAKAYANAGI, Miyagi (JP)

(73) Assignee: ADVANTEST CORPORATION, Tokyo (JP)

(21) Appl. No.: 18/854,694

(22) PCT Filed: May 31, 2022
(86) PCT No.: PCT/JP2022/022155

§ 371 Date: Oct. 7, 2024

(51) Int. Cl. H03H 7/03; H01F 3/08; H01F 3/10

(52) U.S. Cl. CPC H03H 7/03; H01F 3/08; H01F 3/10; H01F 2003/106

(57) ABSTRACT

A biasing circuit includes a signal input terminal, a signal output terminal, a first inductor, and a second inductor. The first inductor is with one end connected to a node between the signal input terminal and the signal output terminal. The second inductor is with one end connected to an other end of the first inductor. The first inductor includes a core that is formed by a bulk of ferrite. The second inductor includes a core that is formed by a bulk of high permeability material.

### TECHNICAL FIELD

The present invention relates to a biasing circuit.

### BACKGROUND ART

There have conventionally been known bias tees in which one end of an inductor is connected to a node between a signal input terminal and a signal output terminal, while the other end of the inductor is grounded. The core of the inductor is formed by solidifying powder of high permeability material with carbon binder or by ferrite of high resistance material to reduce eddy current loss.

It is noted that Patent Literatures 1 and 4 each describe a biasing circuit. Also, Patent Literatures 2 and 3 each describe a filter.

### CITATION LIST

### Patent Literature

Patent Literature 1: Japanese Patent Application Publication No. 2018-078495
Patent Literature 2: Japanese Patent Application Publication No. 2004-040444
Patent Literature 3: Japanese Patent Application Publication No. 2000-151324
Patent Literature 4: Japanese Patent Application Publication No. H7-183766

### SUMMARY OF THE INVENTION

### Technical Problem

However, the core of such an inductor, even if may be formed by solidifying powder of high permeability material with carbon binder or by ferrite of high resistance material as described in the related arts above, can suffer from a reduction in the permeability and therefore the inductance. This can cause the frequency band on the low-frequency side of the output of the signal output terminal to become narrower.

It is hence an object of the present invention to widen the frequency band on the low-frequency side of the output of a biasing circuit.

### Means for Solving the Problem

According to a first aspect of the present invention, a biasing circuit includes: a signal input terminal; a signal output terminal; a first inductor with one end connected to a node between the signal input terminal and the signal output terminal; and a second inductor with one end connected to an other end of the first inductor, wherein the first inductor includes a core that is formed by a bulk of ferrite, and the second inductor includes a core that is formed by a bulk of high permeability material.

According to the thus constructed first aspect of biasing circuit, a first inductor is with one end connected to a node between the signal input terminal and the signal output terminal. A second inductor is with one end connected to an other end of the first inductor. The first inductor includes a core that is formed by a bulk of ferrite. The second inductor includes a core that is formed by a bulk of high permeability material.

According to a second aspect of the present invention, a biasing circuit includes: a signal input terminal: a signal output terminal: a first inductor with one end connected to a node between the signal input terminal and the signal output terminal; and a second inductor with one end connected to an other end of the first inductor, wherein the first inductor includes a core that is formed by molding powder of high permeability material with carbon binder, and the second inductor includes a core that is formed by a bulk of high permeability material.

According to the thus constructed second aspect of biasing circuit, a first inductor is with one end connected to a node between the signal input terminal and the signal output terminal. A second inductor is with one end connected to an other end of the first inductor. The first inductor includes a core that is formed by molding powder of high permeability material with carbon binder. The second inductor includes a core that is formed by a bulk of high permeability material.

According to the biasing circuit of the first and the second aspects of the present invention, the high permeability material may have a specific permeability of higher than 500.

According to the biasing circuit of the first and the second aspects of the present invention, the other end of the second inductor may be grounded.

According to the biasing circuit of the second aspect of the present invention, the core of the first inductor may be formed by molding powder of iron, iron-based nanocrystallized material, high-purity iron, permendur, or silicon steel with carbon binder.

According to the biasing circuit of the first and the second aspects of the present invention, the core of the second inductor may be formed by a bulk of pure iron, amorphous magnetic material, iron-based nanocrystallized material, high-purity iron, permendur, silicon steel, permalloy, or supermalloy.

### BRIEF DESCRIPTION OF DRAWINGS

FIG. 1 is a circuit diagram showing a biasing circuit 1 according to an embodiment of the present invention.

### MODES FOR CARRYING OUT THE INVENTION

A description will now be given of an embodiment of the present invention referring to drawings.

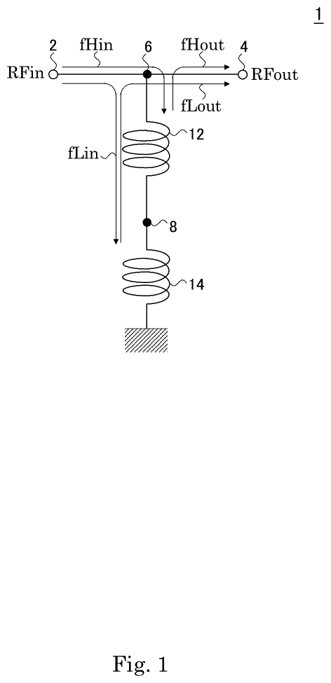

FIG. 1 is a circuit diagram showing a biasing circuit 1 according to an embodiment of the present invention. The biasing circuit 1 according to the embodiment of the present invention includes a signal input terminal (RFin) 2, a signal output terminal (RFout) 4, nodes 6, 8, a first inductor 12, and a second inductor 14. The biasing circuit 1 according to the embodiment of the present invention is a bias tee.

A signal (e.g. high frequency signal) is input to the signal input terminal (RFin) 2. A signal (e.g. high frequency signal) is output from the signal output terminal (RFout) 4. The node 6 is provided between the signal input terminal 2 and the signal output terminal 4.

One end of the first inductor 12 is connected to the node 6. The other end of the first inductor 12 and one end of the second inductor 14 are connected to the node 8. Accordingly, the other end of the first inductor 12 is connected with the one end of the second inductor 14. Also, the other end of the second inductor 14 is grounded.

It is noted that the first inductor 12 and the second inductor 14 each serve as a low pass filter. The cutoff frequency of the first inductor 12 is higher than the cutoff frequency of the second inductor 14.

The first inductor 12 includes a core that is formed by a bulk of ferrite or by molding powder of high permeability material (e.g. iron, iron-based nanocrystallized material, high-purity iron, permendur, or silicon steel) with carbon binder.

The second inductor 14 includes a core that is formed by a bulk of high permeability material (e.g. pure iron, amorphous magnetic material, iron-based nanocrystallized material, high-purity iron, permendur, silicon steel, permalloy, or supermalloy).

It is noted that the high permeability material above means material that is sensitively magnetized by an external magnetic field and has, for example, a specific permeability of higher than 500.

Next will be described an operation according to the embodiment of the present invention.

A signal that has a high frequency component fHin and a low frequency component fLin is input to the signal input terminal (RFin) 2. It is noted that the cutoff frequency of the first inductor 12 is lower than the frequency of the high frequency component fHin but higher than the frequency of the low frequency component fLin. On the other hand, the cutoff frequency of the second inductor 14 is lower than the frequency of the low frequency component fLin.

The high frequency component fHin passes through the node 6, provided to and reflected by the first inductor 12, and output as a high frequency component fHout from the signal output terminal (RFout) 4. Here, the core of the first inductor 12 is formed by a bulk of ferrite or by molding powder of high permeability material with carbon binder and thereby undergoes reduced eddy current loss.

The low frequency component fLin passes through the node 6 and the first inductor 12, provided to and reflected by the second inductor 14, passes through the first inductor 12 and the node 6, and output as a low frequency component fLout from the signal output terminal (RFout) 4.

In accordance with the embodiment of the present invention, the core of the first inductor 12 is formed by a bulk of ferrite or by molding powder of high permeability material with carbon binder and thereby undergoes reduced eddy current loss.

Additionally, in accordance with the embodiment of the present invention, the core of the second inductor 14, which is formed by a bulk of high permeability material, can have higher permeability and therefore higher inductance, whereby the inductor can have a lower cutoff frequency, compared to the core of the first inductor 12, which is formed by a bulk of ferrite or by molding powder of high permeability material with carbon binder.

In addition, since a component with a frequency higher than the cutoff frequency of the second inductor 14 is reflected by the second inductor 14 and output from the signal output terminal (RFout) 4, the frequency band on the low-frequency side of the output of the biasing circuit 1 becomes wider as the second inductor 14 has a lower cutoff frequency.

That is, in accordance with the embodiment of the present invention, since the second inductor 14 can have a lower cutoff frequency, the frequency band on the low-frequency side of the output of the biasing circuit 1 can become wider.

Note here that if a current flowed through the second inductor 14, the eddy current loss in the second inductor 14 would be increased. However, since the low frequency component fLin is reflected by the second inductor 14, no current substantially flows through the second inductor 14. The eddy current loss in the second inductor 14 can therefore be reduced (even though, unlike the first inductor 12, the core is not formed by a bulk of ferrite or by molding powder of high permeability material with carbon binder).

### DESCRIPTION OF REFERENCE NUMERALS

1 Biasing Circuit
2 Signal Input Terminal (RFin)
4 Signal Output Terminal (RFout)
6, 8 Nodes
12 First Inductor
14 Second Inductor
MHin, fHout High Frequency Component
fLin, fLout Low Frequency Component

1. A biasing circuit, comprising:
a signal input terminal;
a signal output terminal;
a first inductor with one end connected to a node between the signal input terminal and the signal output terminal; and
a second inductor with one end connected to an other end of the first inductor, wherein
the first inductor includes a core that is formed by a bulk of ferrite, and
the second inductor includes a core that is formed by a bulk of high permeability material.

2. A biasing circuit, comprising:
a signal input terminal;
a signal output terminal;
a first inductor with one end connected to a node between the signal input terminal and the signal output terminal; and
a second inductor with one end connected to an other end of the first inductor, wherein
the first inductor includes a core that is formed by molding powder of high permeability material with carbon binder, and
the second inductor includes a core that is formed by a bulk of high permeability material.

3. The biasing circuit according to claim 1, wherein
the high permeability material has a specific permeability of higher than 500.

4. The biasing circuit according to claim 1, wherein
the other end of the second inductor is grounded.

5. The biasing circuit according to claim 2, wherein
the core of the first inductor is formed by molding powder of iron, iron-based nanocrystallized material, high-purity iron, permendur, or silicon steel with carbon binder.

6. The biasing circuit according to claim 1, wherein
the core of the second inductor is formed by a bulk of pure iron, amorphous magnetic material, iron-based nanocrystallized material, high-purity iron, permendur, silicon steel, permalloy, or supermalloy.

7. The biasing circuit according to claim 2, wherein
the high permeability material has a specific permeability of higher than 500.

8. The biasing circuit according to claim 2, wherein
the other end of the second inductor is grounded.

9. The biasing circuit according to claim 2, wherein
the core of the second inductor is formed by a bulk of pure iron, amorphous magnetic material, iron-based nanocrystallized material, high-purity iron, permendur, silicon steel, permalloy, or supermalloy.
